(19) United States
(12) Patent Application Publication
(10) Pub. No.: US 2015/0092509 A1
(43) Pub. Date: Apr. 2, 2015

(54) SEMICONDUCTOR APPARATUS AND CHIP ID GENERATION METHOD THEREOF

(71) Applicant: SK hynix Inc., Icheon-si Gyeonggi-do (KR)

(72) Inventor: Ju Young KIM, Icheon-si Gyeonggi-do (KR)

(73) Assignee: SK hynix Inc., Icheon-si Gyeonggi-do (KR)

(21) Appl. No.: 14/100,479

(22) Filed: Dec. 9, 2013

(30) Foreign Application Priority Data
Sep. 30, 2013 (KR) 10-2013-0116512

(51) Int. Cl. G11C 8/12; G01K 7/01

(52) U.S. Cl. CPC G11C 8/12; G01K 7/01; G01K 2219/00
USPC 365/230.01; 374/170

(57) ABSTRACT

Provided is a semiconductor apparatus including a plurality of memory chips which are sequentially stacked. Each of the memory chips includes: a temperature sensor configured to sense the temperature of the memory chip; and a chip ID output unit configured to generate a chip ID for the memory chip based on an output of the temperature sensor.

### CROSS-REFERENCES TO RELATED APPLICATION

The present application claims priority under 35 U.S.C. §119(a) to Korean application number 10-2013-0116512, filed on Sep. 30, 2013, in the Korean Intellectual Property Office, which is incorporated herein by reference in its entirety.

### BACKGROUND

1. Technical Field

Various embodiments generally relate to a semiconductor apparatus fabricated through a three-dimensional (3D) arrangement technology and a chip ID generation method thereof.

2. Related Art

Recently, much attention has been paid to a 3D arrangement technology in which a plurality of memory chips are stacked to improve an integration degree, instead of a two-dimensional (2D) arrangement technology.

The 3D arrangement technology has an advantage in that the same function may be implemented on a small footprint because the area of the XY plane may be reduced through integration along the z-axis. Representative examples of the 3D arrangement technology may include through silicon via (TSV) technology, and the TSV technology has an advantage in that capacitance may be reduced much more than in the 2D arrangement technology.

According to the TSV technology, a path is formed to pass through a plurality of memory chips, and an electrode is formed in the path so as to perform communication between the respective memory chips and a controller.

A semiconductor apparatus including a plurality of chips based on the TSV technology assigns different chip IDs to the respective chips, in order to select a desired chip.

In other words, different chips IDs are assigned to the respective chips, and a system including the semiconductor apparatus may input a chip select code to the semiconductor apparatus through a controller so as to select a desired chip in the semiconductor device.

The chip IDs are assigned as follows: two or more pins using a TSV are provided to apply a power supply voltage VDD and a is ground voltage VSS at all times, and the data are received and decoded to assign a chip ID.

Thus, since the conventional semiconductor apparatus must include separate TSVs for two or more chip ID pins, the area of the chips inevitably increases. Furthermore, since the chip ID pins are separately provided, the total number of pins increases. Furthermore, the conventional semiconductor apparatus has a limitation in stacking chips because the TSVs for the chip ID pins are separately provided.

### SUMMARY

Various embodiments are generally directed to a semiconductor apparatus capable of generating ID chips while preventing the increase in area of chips or the increase in number of pins, and a chip ID generation method thereof.

In an embodiment of the present invention, there is provided a semiconductor apparatus including a plurality of memory chips which are sequentially stacked. Each of the memory chips includes: a temperature sensor configured to sense the temperature of the memory chip; and a chip ID output unit configured to generate a chip ID for the memory chip from an output of the temperature to sensor.

In an embodiment of the present invention, there is provided a chip ID generation method for a semiconductor apparatus including a plurality of memory chips stacked therein. The chip ID generation method includes the steps of: outputting different is temperature values of the respective memory chips through temperature sensors installed in the respective memory chips; and generating chip IDs for the respective memory chips, based on the temperature values outputted from the respective temperature sensors.

In an embodiment of the present invention, there is provided a semiconductor apparatus including a plurality of memory chips which are stacked, wherein at least one memory chip includes: a temperature sensor configured to sense the temperature of the memory chip; and a chip identification (ID) output unit configured to generate a chip ID for the memory chip based on an output of the temperature sensor.

### BRIEF DESCRIPTION OF THE DRAWINGS

Features, aspects, and embodiments are described in conjunction with the attached drawings, in which:

FIG. 1 is a schematic view illustrating an example of a semiconductor apparatus including a plurality of chips;

FIG. 2 is a diagram illustrating a semiconductor apparatus according to an embodiment of the present invention;

FIG. 3 is a diagram illustrating the detailed configuration of a memory chip of FIG. 2;

FIG. 4 is a flowchart for explaining a chip ID generation method for a semiconductor apparatus according to an embodiment of the present invention;

FIG. 5 is a diagram illustrating a semiconductor apparatus according to an embodiment of the present invention; and

FIG. 6 is a flowchart for explaining a chip ID generation method for a semiconductor apparatus according to an embodiment of the present invention.

### DETAILED DESCRIPTION

Hereinafter, a semiconductor apparatus and a chip ID generation method thereof according to the present invention will be described below with reference to the accompanying drawings through various examples of embodiments. According to the embodiments of the present invention, the semiconductor apparatus includes four memory chips. However, the number of memory chips does not limit the scope of the present invention.

Referring to FIG. 1, a semiconductor apparatus according to an embodiment of the present invention includes an interposer 110 and a plurality of memory chips 120A, 120B, 120C, and 120D stacked over the interposer 110.

The interposer 110 serves to transmit a signal from a control unit (not illustrated) such as a host, a controller, or a CPU to the plurality of memory chips 120A, 120B, 120C, and 120D or transmit signals from the plurality of memory chips 120A, 120B, 120C, and 120D to the control unit.

Each of the memory chips 120A, 120B, 120C, and 120D may include various circuit blocks (not illustrated) for implementing is the function of the semiconductor apparatus. Each of the memory chips 120A, 120B, 120C, and 120D includes a plurality of TSVs 121 formed therein. The TSV 121 serves as a path for transmitting various signals of the respective memory chips 120A, 120B, 120C, and 120D through the interposer 110 or transmitting signals provided through the interposer 110 to a selected memory chip. Furthermore, the TSV 121 serves to transmit signals between the respective memory chips 120A, 120B, 120C, and 120D.

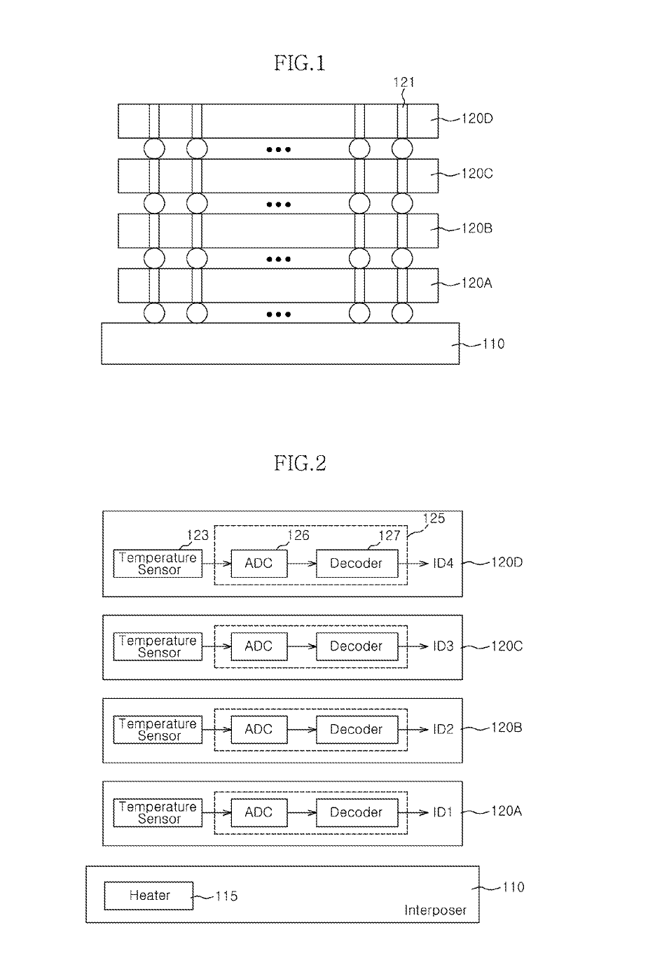

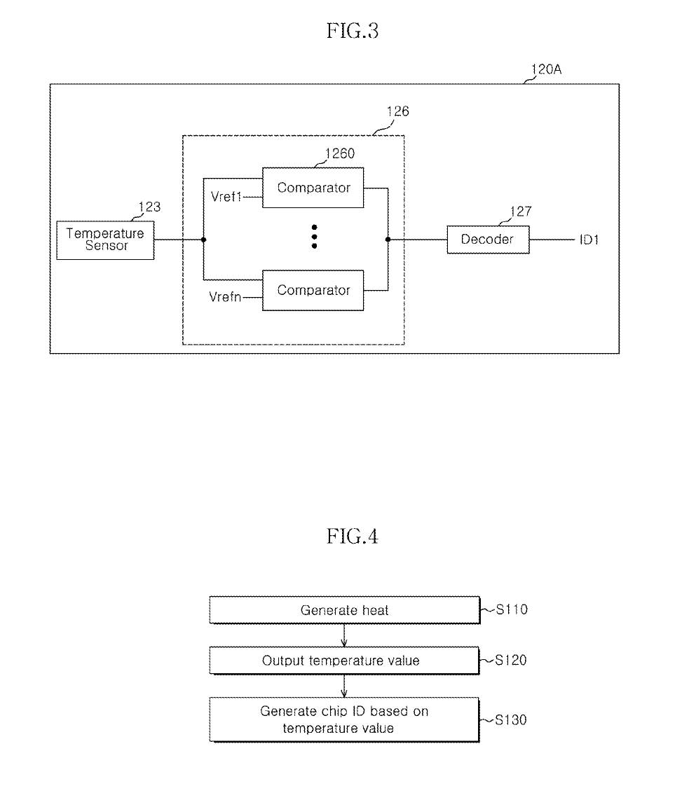

Referring to FIGS. 2 and 3, the interposer 110 of the semiconductor apparatus according to the embodiments of the present invention include a heater 115. The heater 115 may include a resistor, and various units other than the resistor may be applied as long as they can generate heat.

Each of the memory chips 120A, 120B, 120C, and 120D may include a temperature sensor 123 and a chip ID output unit 125.

The temperature sensor 123 is configured to sense the temperature of the memory chip having the temperature sensor 123 installed therein. Simultaneously, the temperature sensor 123 outputs the sensed temperature value as an analog value. For example, the temperature sensor 123 may output the temperature to value of the memory chip as a voltage value.

The chip ID output unit 125 may include an analog-to-digital converter (ADC) 126 and a decoder 127.

The ADC 126 is configured to convert the analog voltage value outputted from the temperature sensor 123 into a digital signal. Referring to FIG. 3, the ADC 126 may include a plurality of comparators 1260. Each of the comparators 1260 is configured to compare the voltage value outputted from the temperature sensor 123 to a reference voltage value Vref (i.e., Vref1 to Vrefn, where n is a number greater than 1) and output a digital signal according to the comparison result.

For example, when the voltage value outputted from the temperature sensor 123 is higher than a reference voltage value of a predetermined comparator, the comparator may output a value of 1, and when the voltage value outputted from the temperature sensor 123 is lower than the reference voltage value of the comparator, the comparator may output a value of 0.

That is, the ADC 126 may compare the voltage value outputted from the temperature sensor 123 through the plurality of comparators 1260, and output a digital signal.

The decoder 127 is configured to decode the digital signal outputted from the ADC 126 and generate a chip ID (i.e., ID1, ID2, ID3, or ID4) for the memory chip.

The process of generating a chip ID for each of the memory chips of the semiconductor apparatus according to the embodiments to of the present invention is performed as follows.

Referring to FIG. 4, the heater 115 of the interposer 110 generates heat at step S110. The heat generated from the heater 115 is transmitted to the plurality of memory chips 120A, 120B, 120C, and 120D. The temperature of the heat transmitted to each of the memory chips 120A, 120B, 120C, and 120D differs depending on the position of the memory chip.

Then, the temperature of the heat transmitted from the heater 115 is sensed through the temperature sensor 123 installed in each of the memory chips 120A, 120B, 120C, and 120D. At this time, the temperature sensed through the temperature sensor 123 installed in each of the memory chips 120A, 120B, 120C, and 120D is higher as the memory chip is closer to the interposer 110, and lower as the memory chip more remote from the interposer 110.

For example, when the temperature of the heat generated from the heater 115 is 90° C., the temperature sensed through the temperature sensor 123 of the first memory chip 120A may be 89° C. Furthermore, the temperature of the second memory chip 120B may be 88° C., the temperature of the third memory chip 120C may be 87° C., and the temperature of the fourth memory chip 120D may be set 87° C.

In other words, the temperatures values of the respective memory chips 120A, 120B, 120C, and 120D, sensed through the temperature sensors 123 of the respective memory chips 120A, 120B, 120C, and 120D, may gradually decrease to predetermined temperatures depending on the positions of the respective memory chips 120A, 120B, 120C, and 120D.

During the above-described process, the temperature values of the memory chips 120A, 120B, 120C, and 120D, sensed through the respective temperature sensors 123, may be outputted as analog is voltage values (See step S120, Output temperature value).

Then, based on the analog voltage values outputted from the temperature sensors 123, the ADCs 126 of the respective memory chips 120A, 120B, 120C, and 120D generate chip IDs at step S130 (i.e., Generate chip ID based on temperature value).

Specifically, the voltage values outputted from the respective temperature sensors 123 are converted into digital signals through the respective ADCs 126.

Each of the ADC 126 includes the plurality of comparators 1260. During the above-described process, the digital signal for each of the memory chips 120A, 120B, 120C, and 120D may be outputted by comparing the voltage value outputted from the temperature sensor 123 through the plurality of comparators 1260.

Then, the decoders 127 of the respective memory chips 120A, 120B, 120C, and 120D decodes the output digital signals.

The chip IDs generated for the respective memory chips through the above-described process may be used to select a desired memory chip when the system inputs a chip select code to the semiconductor apparatus through the controller.

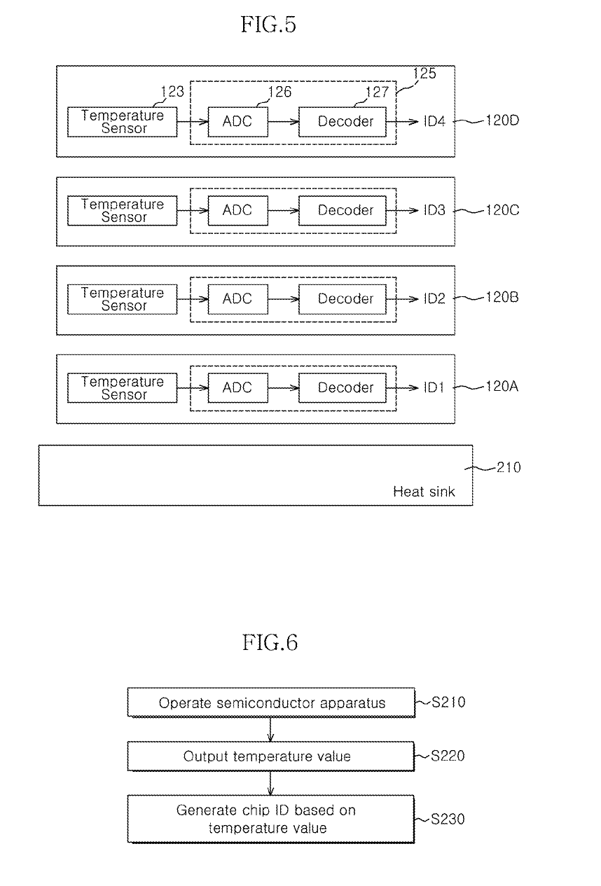

FIG. 5 illustrates a semiconductor apparatus according to an to embodiment of the present invention.

Referring to FIG. 5, the semiconductor apparatus according to the embodiments of the present invention include a heat sink 210 and a plurality of memory chips 120A, 120B, 120C, and 120D stacked over the heat sink 210.

The heat sink 210 serves to dissipate heat generated when the semiconductor apparatus is operated. The heat sink 210 is contacted with the first memory chip 120A disposed at the lowermost layer.

Since the memory chips have the same configuration as the above-described embodiments, the detailed descriptions thereof are omitted herein. However, the temperature sensors 123 sense the temperatures of the respective memory chips 120A, 120B, 120C, and 120D when the semiconductor apparatus is operated, unlike the above-described embodiments.

The process of generating chip IDs for the respective memory chips of the semiconductor apparatus according to the embodiments of the present invention will be described as follows.

Referring to FIG. 6, the semiconductor apparatus is operated, that is, test-driven at step S210. When the semiconductor apparatus is operated, heat is generated. Among the plurality of memory chips 120A, 120B, 120C, and 120D, the memory chip 120D at the uppermost layer has the highest temperature, and the memory chip 120A at the lowermost layer has the lowest temperature.

This is because, since the memory chip 120A at the to lowermost layer among the memory chips is contacted with the heat sink 210, the memory chip 120A may easily emit heat, and the heat generated from the memory chip 120D at the uppermost layer may not be easily transmitted to the heat sink 210.

The reason why the heat generated from the uppermost memory chip 120D is not easily transmitted to the heat sink 210 is that the heat conductivity (0.005 W/mK) of an insulator (for example, epoxy) connecting the respective memory chips 120A, 120B, 120C, and 120D is much lower than the heat conductivity (150 W/mK) of silicon or the heat conductivity (285 W/mK) of a metallic wiring (for example, copper).

The temperature sensors 123 installed in the respective memory chips 120A, 120B, 120C, and 120D sense the temperature values of the heats generated during the operations of the respective memory chips 120A, 120B, 120C, and 120D, and output analog voltage values based on the temperature values, at step S220.

Then, the ADCs 126 of the respective memory chips 120A, 120B, 120C, and 120D generate chip IDs for the respective memory chips 120A, 120B, 120C, and 120D, based on the analog voltage values outputted from the temperature sensors 123, at step S230.

Specifically, the voltage values outputted from the respective temperature sensors 123 are converted into digital signals through the ADCs 126.

Each of the ADCs 126 includes a plurality of comparators 1260. During the above-described process, the digital signal for each of the memory chips 120A, 120B, 120C, and 120D may be outputted by comparing the voltage value outputted from the temperature sensor 123 through the plurality of comparators 1260.

Then, the decoders 127 of the respective memory chips 120A, 120B, 120C, and 120D decode the output digital signals.

The chip IDs generated for the respective memory chips through the above-described process may be used to select a desired memory chip when the system inputs a chip select code to the semiconductor apparatus through the controller.

According to the embodiments of the present invention, since the temperature values sensed through the temperature sensors of the respective memory chips are used while the chip IDs for the respective memory chips are generated, the area of the memory chips is not increased, unlike the conventional memory apparatus which includes separate TSVs for chip IDs.

Furthermore, since the semiconductor apparatus according to the embodiments of the present invention does not include chip ID pins, the number of pins does not increase.

Furthermore, unlike the conventional semiconductor which has a limitation in stacking memory chips because a plurality of TSVs are needed, the semiconductor apparatus according to the embodiments of the present invention has no limitation in stacking memory chips as long as the temperatures of the stacked memory chips may gradually decrease or increase. That is, the semiconductor apparatus according to the embodiments of the present invention may include a larger number of layers stacked therein than the conventional semiconductor apparatus.

While various embodiments have been described above, it will be understood to those skilled in the art that the embodiments described are by way of example only. Accordingly, the is semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising a plurality of memory chips which are sequentially stacked,
wherein each of the memory chips comprises:
a temperature sensor configured to sense the temperature of the memory chip; and
a chip identification (ID) output unit configured to generate a chip ID for the memory chip based on an output of the temperature to sensor.

2. The semiconductor apparatus according to claim 1, wherein the plurality of memory chips are stacked over an interposer including a heater to generate heat.

3. The semiconductor apparatus according to claim 1, wherein the plurality of semiconductor chips are stacked over a heat sink which is configured to absorb heat from the respective memory chips.

4. The semiconductor apparatus according to claim 1, wherein the chip ID output unit comprises:
an analog-to-digital converter (ADC) configured to convert the output of the temperature sensor into a digital signal; and
a decoder configured to decode the digital signal outputted from the ADC.

5. The semiconductor apparatus according to claim 1, wherein the plurality of memory chips are coupled through a plurality of through-chip vias (TSVs).

6. A chip identification (ID) generation method for a semiconductor apparatus including a plurality of memory chips stacked therein, comprising the steps of:
outputting different temperature values of the respective memory chips through temperature sensors included in the respective memory chips; and
generating chip IDs for the respective memory chips, based on the temperature values outputted from the respective temperature is sensors.

7. The chip ID generation method according to claim 6, wherein the plurality of memory chips are stacked over an interposer including a heater installed therein, and
the chip ID generation method further comprises the step of operating the heater to transmit heat to the respective memory chips, before the step of outputting the different temperature values of the respective memory chips.

8. The chip ID generation method according to claim 7, wherein in the step of operating the heater to transmit heat to the respective memory chips,
the temperature of each of the memory chips is lower as the memory chip is more remote from the heater.

9. The chip ID generation method according to claim 8, wherein in the step of outputting the different temperature value of the respective memory chips,
the respective temperature sensors output the sensed to temperature values as voltage values.

10. The chip ID generation method according to claim 9, wherein the step of generating the chip IDs for the respective memory chip comprises the step of converting the temperature values outputted from the respective temperature sensors into digital signals and decoding the digital signals.

11. The chip ID generation method according to claim 6, wherein the plurality of memory chips are stacked over a heat sink, and
the chip ID generation method further comprises the step of operating the semiconductor apparatus, before the step of outputting the different temperature values of the respective memory chips.

12. The chip ID generation method according to claim 11, wherein in the step of operating the semiconductor apparatus, the temperature of each of the memory chips is higher as the memory chip is more remote from the heat sink.

13. The chip ID generation method according to claim 12, wherein in the step of outputting the different temperature values of the respective memory chips,
the respective temperature sensors output the sensed temperature values as voltage values.

14. The chip ID generation method according to claim 13, wherein the step of generating the chip IDs for the respective memory chips comprises the step of converting the temperature values outputted from the respective temperature sensors into digital signals and decoding the digital signals.

15. A semiconductor apparatus comprising a plurality of memory chips which are stacked,
wherein at least one memory chip comprises:
a temperature sensor configured to sense the temperature of the memory chip; and
a chip identification (ID) output unit configured to generate a chip ID for the memory chip based on an output of the temperature sensor.

16. The semiconductor apparatus according to claim 15, wherein the plurality of memory chips are stacked adjacent to an interposer.

17. The semiconductor apparatus according to claim 15, wherein the plurality of semiconductor chips are stacked adjacent to a heat sink.

18. The semiconductor apparatus according to claim 15, wherein the plurality of memory chips are coupled through a through-chip vias (TSVs).
